(19) United States
(12) Patent Application Publication
(10) Pub. No.: US 2012/0218730 A1
(43) Pub. Date: Aug. 30, 2012

(54) SEALING STRUCTURE

(75) Inventor: Harumi KAWASE, Makinohara-shi (JP)

(73) Assignee: YAZAKI CORPORATION, Tokyo (JP)

(21) Appl. No.: 13/398,913

(22) Filed: Feb. 17, 2012

(30) Foreign Application Priority Data
Feb. 24, 2011 (JP) 2011-037916

(51) Int. Cl. H05K 7/12

(52) U.S. Cl. 361/807

(57) ABSTRACT

In a sealing structure, an elongated projecting portion is formed on an outer circumferential surface of a holder in a position forward in an inserting direction of the holder than an annular packing, the elongated projecting portion projects than the annular packing in a radial direction of the holder, a recess portion is formed on an inner circumferential surface of an opening portion of the holder so that the elongated projecting portion is inserted therein, and the recess portion has such a depth that the annular packing is pressed by the inner circumferential surface of the opening portion in a state where the elongated projecting portion is inserted into the recess portion.

### BACKGROUND

The present invention is related to a sealing structure.

There are known a sealing structure including a housing which is formed with an accommodation space for an electronic part and a cylindrical holder which holds an electronic part and a wire connected to the electronic part. In this sealing structure, an electronic part is inserted into the housing from an opening portion opened in the housing with the electronic part caused to face the accommodation space, and a gap between the holder and the opening portion is sealed with the holder installed in the opening portion.

For example, Patent Document 1 discloses an annular packing which is formed of an elastic material for use in the sealing structure. Namely, by mounting a packing on an outer circumferential surface of the holder, a gap between the outer circumferential surface of the holder and an inner circumferential surface of the housing is sealed by the packing along the entire circumference of the holder.

Incidentally, according to the sealing structure described above, when the holder with the packing mounted therearound is inserted into the housing, the holder is inserted with an outer circumferential surface of the packing pressed against the inner circumferential surface of the housing. Because of this, for example, when large friction is generated between the outer circumferential surface of the packing and the inner circumferential surface of the housing, the packing may be turned or twisted during the insertion of the holder, deteriorating the sealing performance of the gap defined between the holder and the housing.
[Patent Document 1] JP-A-2005-19287

### SUMMARY

It is therefore one advantageous aspect of the present invention to provide a sealing structure which can prevent the turning or twisting of the packing when the holder is inserted into the housing.

According to one advantage of the invention, there is provided a sealing structure comprising:

a housing, having an accommodation space for accommodating an electronic part and an opening portion communicated with the accommodation space;

a holder, holding the electronic part and a wire connected to the electronic part, and configured to be inserted into the opening portion in an axial direction of the holder; and

an annular packing provided on an outer circumferential surface of the holder, and configured to be disposed between an inner circumferential surface of the opening portion and the outer circumferential surface of the holder so as to seal off the accommodation space in a state where the holder is inserted in the housing,

wherein an elongated projecting portion is formed on the outer circumferential surface of the holder in a position forward in an inserting direction of the holder than the annular packing,

wherein the elongated projecting portion projects than the annular packing in a radial direction of the holder,

wherein a recess portion is formed on the inner circumferential surface of the opening portion so that the elongated projecting portion is inserted therein, and

wherein the recess portion has such a depth that the annular packing is pressed by the inner circumferential surface of the opening portion in a state where the elongated projecting portion is inserted into the recess portion.

The elongated projecting portion may be formed along an entire circumference of the outer circumferential surface of the holder.

The elongated projecting portion may include a plurality of projections formed at plural circumferential locations on the outer circumferential surface of the holder.

### BRIEF DESCRIPTION OF DRAWINGS

FIG. 1 is an axial sectional view of a sealing structure according to an embodiment of the invention.

FIG. 2 is an exploded perspective view of the sealing structure shown in FIG. 1.

FIGS. 3A and 3B show explanatory diagrams illustrating assembling operations of the sealing structure shown in FIG. 1. FIG. 3A is a diagram illustrating a state in which a holder is being inserted, and FIG. 3B is a diagram illustrating a state in which the holder is completely inserted.

FIG. 4 is an exploded perspective view of a housing unit to which the sealing structure of the invention is applied.

FIG. 5 is an external view of the housing unit shown in FIG. 1.

FIG. 6 is a perspective view of a different form of a sealing structure according to the present invention.

### DETAILED DESCRIPTION OF EXEMPLIFIED EMBODIMENTS

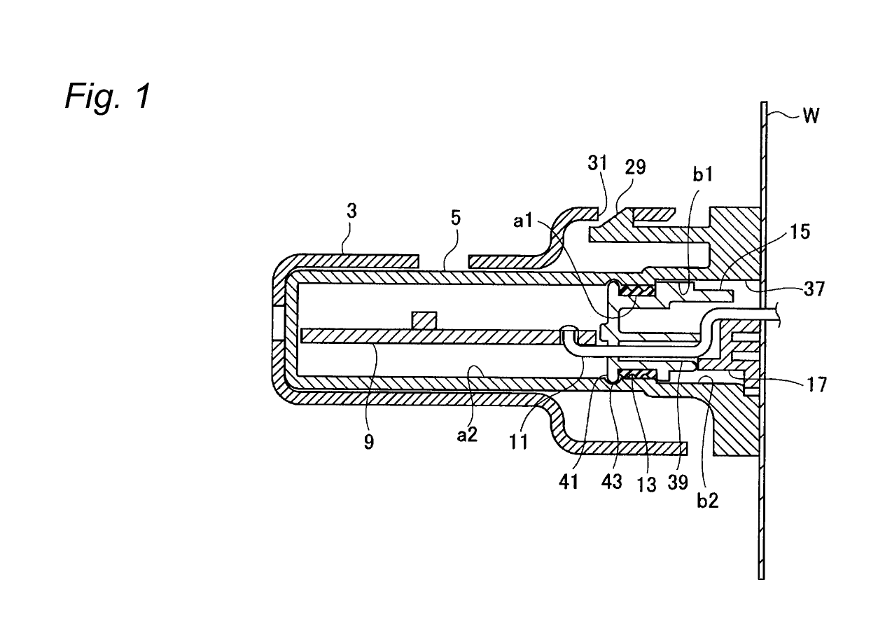

Hereinafter, an embodiment of a sealing structure of the invention will be described specifically by reference to FIGS. 1 to 6. In this embodiment, a sealing structure for a waterproof housing which accommodates an LED unit will be described. However, the sealing structure of the invention is not limited the application to the waterproof housing which accommodates an LED unit but can also be applied as a sealing structure for a housing which accommodates a general electronic unit.

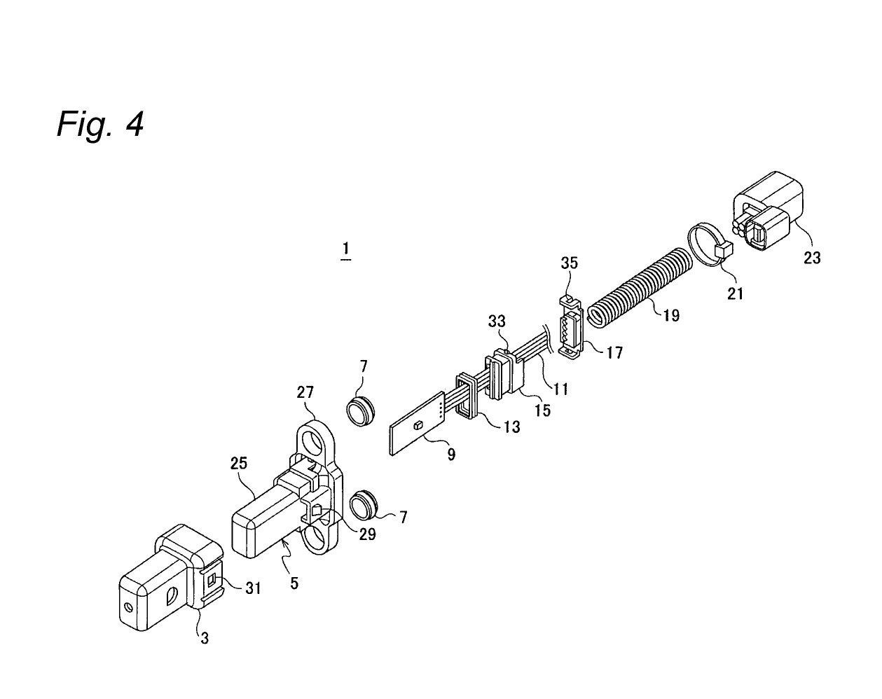

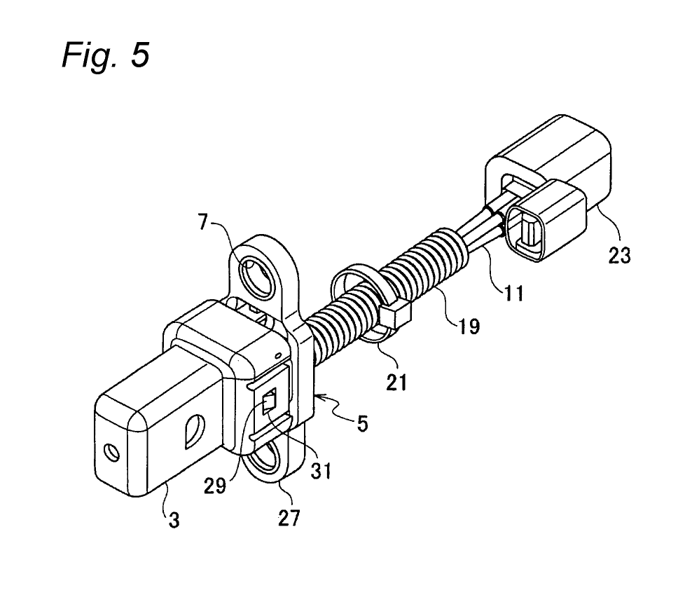

FIGS. 4 and 5 show a configuration of a housing unit provided with a waterproof housing (a housing) to which a sealing structure of this embodiment is applied. A housing unit 1 of the embodiment includes a housing cover 3, a housing 5, collars 7, an LED unit 9, wires 11, a packing 13, a holder 15, a holder cover 17, an electrical wire protection pipe 19, a clip 21, and a connector 23.

The housing 5 is formed from a synthetic resin which transmits light and includes a cylindrical portion 25 in which an accommodation space for the LED unit 9 is defined, an opening portion which is communicated with the accommodation space and guides the LED unit 9 into the accommodation space defined in the cylindrical portion 25 and a flange portion 27 which supports the cylindrical portion 25 on a wall surface of a mating member. The housing cover 3 is mounted properly on the cylindrical portion 25 when a projecting 29 on the cylindrical portion 25 is brought into engagement with a hole 31 in the housing cover 3 in such a state that the housing cover 3 is placed on the cylindrical portion 25. Two holes are formed in the flange portion 27, the collars 7, which are made of metal and which have a cylindrical shape, are installed in the corresponding holes, so that bolts are inserted through insides of the collars 7. The collars 7 may be insert molded in the housing 5.

The holder 15 is formed from synthetic resin into a cylindrical shape and is adapted to hold the LED unit 9 such as a circuit board and the wires 11 which are electrically connected to the LED unit 9. The LED unit 9 is held at an axial end of the holder 15, while the wires 11 are passed through a hole in the holder 15 so as to be led out from a lead-out portion at the other end of the holder 15.

An outer circumferential surface of the holder 15 forms rectangular circumferential section. A rectangular sectional area of the holder 15 which is orthogonal to an axial direction of the holder 15 is smaller at one end than at the other end in the axial direction. Thus, whole shape of the holder 15 is a stepped shape. The holder cover 17, which is curved or bent at ends, is placed on an outer circumferential surface of the holder 15 at the other end where the section is larger. Two projections 33 are formed on the holder 15, and when these projections 33 are brought into engagement with holes 35 formed in end portions of the holder cover 17, the holder cover 17 is mounted properly on the holder 15. The wires 11 which are led out of the holder 15 are passed through a through hole formed in the holder cover 17. In addition, the sectional shape of the outer circumferential surface of the holder 15 may be rectangular, triangular, circular and any other shapes that correspond to an opening portion 37 of the housing 5.

The annular packing 13, which is made up of rectangular circumferential sides, is mounted on the circumferential surface of the holder 15 at the one end where the section is smaller. The holder 15 on which the packing 13 and the holder cover 17 are now mounted is inserted into the housing 5 from the opening portion 37 formed in the housing 5 with the LED unit 9, which is supported at the one end of the holder 15, caused to face the accommodation space in the housing 5. The holder 15 is then mounted in the opening portion. In addition, the shape of the packing 13 may be rectangular, triangular, circular and any other shapes that suit a circumferential shape of the circumferential surface of the holder 15.

The wires 11 which are led out of the lead-out portion of the holder cover 17 are inserted through the electric wire protection pipe 19 and the clip 21 so as to be connected to ends of terminals provided in the connector 23. For example, a mating connector (not shown) which is connected to an external electronic device is connected to the connector 23.

The housing unit 1 is mounted on a mating wall surface W (refer to FIG. 1), not shown, by fastening bolts which pass through the collars 7 in the flange portion 27 into bolt holes in the wall surface in such a state that for example, the electric wire protection pipe 19 which accommodates the wires 11, as is shown in FIG. 5, is inserted through an opening in the wall surface.

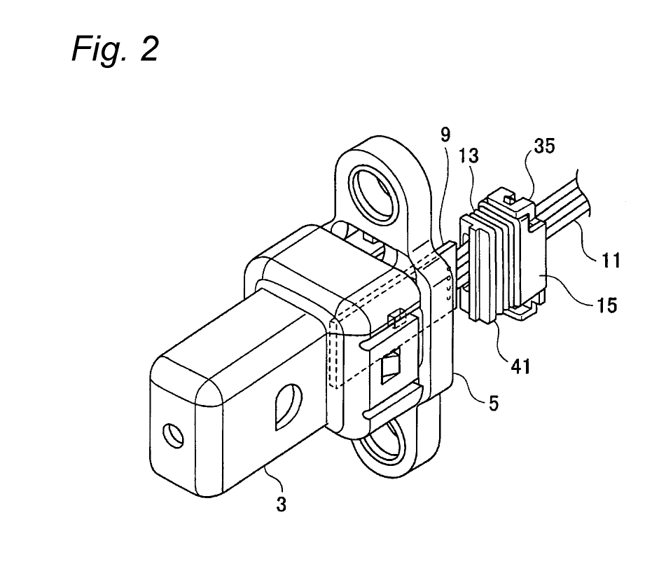

Next, a sealing structure of the housing 5 of the embodiment will be described specifically by reference to FIGS. 1 and 2.

The holder 15 is mounted in the opening portion 37 opened in the housing 5, and the LED unit 9 which is held on the holder 15 is disposed in the accommodation space which is defined in a deeper portion in the housing 5 than the opening portion 37. The accommodation space in the housing 5 is sealed off by the opening portion 37 being sealed by the holder 15 which is inserted from the opening portion 37 and the packing 13. The wires 11 which are connected to the LED unit 9 pass through a through hole 39 formed in the holder 15 and are then led out from the lead-out portion, and a gap between the wires 11 and the through hole 39 is sealed by a known structure.

The holder 15 has a step-shaped section in the axial direction. An outer circumferential surface a1 which is positioned at the one end of the holder 15 and supports the LED unit 9 has vertical and horizontal dimensions in a sectional plane orthogonal to the axial direction of the holder 15. An outer circumferential surface b1 which is positioned at the other end of the holder 15 has vertical and horizontal dimensions in a sectional plane orthogonal to the axial direction of the holder 15. The vertical and horizontal dimensions of the outer circumferential surface a1 are respectively smaller than the vertical and horizontal dimensions of the outer circumferential surface b1.

In the housing 5, an inner circumferential surface of the accommodation space for the LED unit 9 which is defined inside the cylindrical portion 25 forms rectangular circumferential section, and has a step-like shape in the axial direction. An inner circumferential surface a2 which is positioned at a deeper end of the accommodation space has vertical and horizontal dimensions in a rectangular sectional plane orthogonal to the axial direction of the holder 15. An inner circumferential surface b2 which is positioned at an opening portion 37 of the accommodation space has vertical and horizontal dimensions in a rectangular sectional plane orthogonal to the axial direction of the holder 15. The vertical and horizontal dimensions of the inner circumferential surface a2 are respectively smaller than the vertical and horizontal dimensions of the inner circumferential surface b2.

A stepped portion on the holder 15 which constitutes a border between the outer circumferential surface a1 and the outer circumferential surface b1 is brought into abutment with a stepped portion on the housing 5 which constitutes a border between the inner circumferential surface a2 and the inner circumferential surface b2. Namely, the outer circumferential surface a1 of the holder 15 is disposed so as to face the inner circumferential surface a2 of the housing, and the outer circumferential surface b1 of the holder 15 is disposed so as to face the inner circumferential surface b2 of the housing 5. Consequently, the outer circumferential surface of the packing 13 which is mounted on the outer circumferential surface a1 of the holder 15 is pressed inwards by the inner circumferential surface a2 of the housing, whereby a gap between the outer circumferential surface a1 of the holder 15 and the inner circumferential surface a2 of the housing 5 is sealed. The outer circumferential surface of the packing 13 has a wavy shape, however, the shape of the outer circumferential surface of the packing 13 is not limited thereto.

An annular elongated projecting portion 41 (a elongated projecting portion) is formed on the outer circumferential surface a1 of the holder 15 in a position lying further frontward in the inserting direction, that is, deeper in the accommodation space than the position where the packing 13 is mounted. The elongated projecting portion 41 is formed so as to project substantially perpendicular to the outer circumferential surface a1. This elongated projecting portion is formed so as to project higher than the outer circumferential surface of the packing 13 on the outer circumferential surface a1 of the holder 15 as viewed in the section in the axial direction of the holder 15. A distal end of the elongated projecting portion 41 is rounded along the entire circumference thereof. In other words, the elongated projecting portion 41 is formed on the outer circumferential surface of the holder 15 in a position forward in the inserting direction of the holder 15 than the packing 13, and the elongated projecting portion 41 projects than the packing 13 in a radial direction of the holder 15.

An annular recess portion 43 is formed on the inner circumferential surface a2 of the housing 5 so that the elongated projecting portion is inserted thereinto. A depth of the recess portion 43 from the inner circumferential surface a2 is set to such a range that the outer circumferential surface of the packing 13 is pressed inwards with a predetermined pressure by the inner circumferential surface a2 of the housing when the elongated projecting portion 41 is inserted into the recess portion 43. The predetermined pressure is determined as a pressure required to ensure a predetermined sealing performance. A groove bottom in the recess portion 43 is rounded along the entire circumference thereof. Consequently, the elongated projecting portion 41 on the holder 15 is inserted in the recess portion 43 on the housing 5 when the stepped portion constituting the border between the outer circumferential surface a1 and the outer circumferential surface b1 of the holder 15 is brought into abutment with the stepped portion constituting the border between the inner circumferential surface a2 and the inner circumferential surface b2 of the housing 5, whereupon the outer circumferential surface of the packing 13 is pressed inwards by the inner circumferential surface a2 of the housing 5.

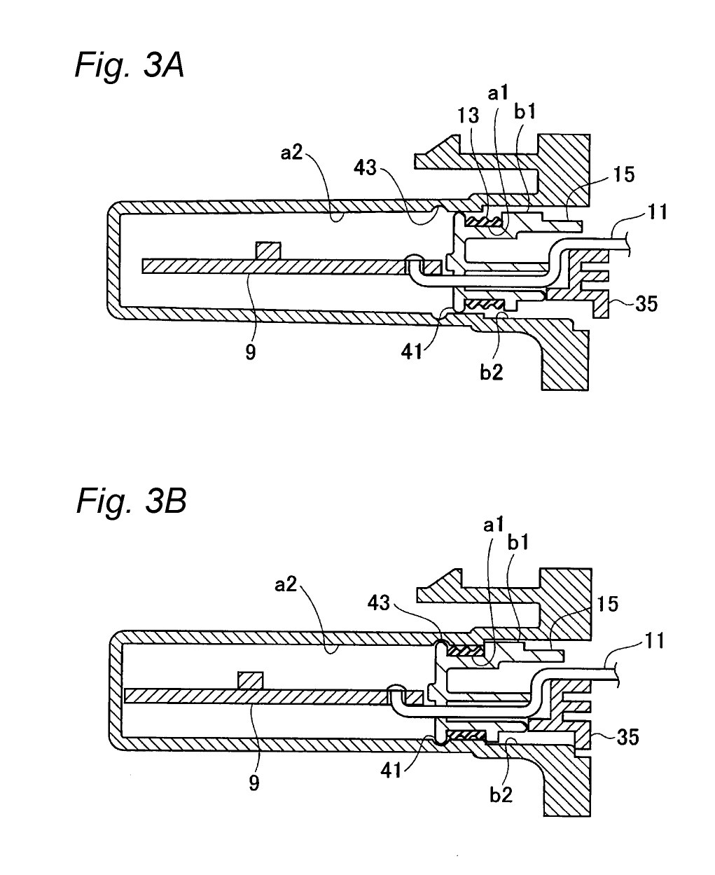

Next, a function when fabricating the sealing structure of the embodiment will be described by reference to FIGS. 3A and 3B. Firstly, a holder 15 is prepared on which a packing 13 and a holder cover 17 are mounted and which holes an LED unit 9. Then, the holder 15 is inserted from the opening portion 37 with the LED unit 9 caused to face the accommodation space in the housing 5.

Here, a rectangular section of the elongated projecting portion 41 which is orthogonal to the axial direction of the holder 15 is formed larger in either of vertical and horizontal directions than the rectangular section of the housing 5 which is orthogonal to the axial direction of the accommodation space. Consequently, as shown in FIG. 3A, the elongated projecting portion 41 of the holder 15 is in abutment with the inner circumferential surface a2 of the housing 5 along the entire circumference thereof and is inserted and press fitted so as to forcibly expand the opening portion 37. Because of this, the outer circumferential surface of the packing 13 which is mounted on the holder 15 is allowed to move within the accommodation space without being brought into abutment with the inner circumferential surface a2 of the housing 5.

Following this, in the holder 15 inserted into the housing 5, as shown in FIG. 3B, the stepped portion which constitutes the border between the outer circumferential surface a1 and the outer circumferential surface b1 of the holder 15 is brought into abutment with the stepped portion which constitutes the border between the inner circumferential surface a2 and the inner circumferential surface b2 of the housing 5. In addition, the elongated projecting portion 41 is inserted in the recess portion 43 formed on the inner circumferential surface a2 of the housing 5 along the entire circumference thereof. As a result, the inner circumferential surface a2 of the housing 5 is released from being pressed outwards by the elongated projecting portion 41 and is then allowed to act in a direction in which the outer circumferential surface of the packing 13 is pressed inwards. As a result, a gap between the outer circumferential surface a1 of the holder 15 and the inner circumferential surface a2 of the housing 5 is sealed by the packing 13.

In this way, in the embodiment, the elongated projecting portion 41 is provided on the outer circumferential surface a1 of the holder 15 which is inserted from the opening portion 37 in the housing 5, and the recess portion 43 is provided on the inner circumferential surface a2 of the housing 5 so that the elongated projecting portion 41 is inserted thereinto. Therefore, the packing 13 is allowed to move in the inserting direction without being brought into contact with the inner circumferential surface a2 of the housing 5. Consequently, when the holder 15 moves within the accommodation space, no external force acts on the packing 13. Therefore, the packing 13 can be prevented from being turned or twisted, thereby making it possible to enhance the waterproofness of the housing 5.

In addition, when the elongated projecting portion 41 is inserted into the recess portion 43, the packing 13 is pressed inwards by the inner circumferential surface a2 of the housing 5. However, as this occurs, the stepped portion constituting the border between the outer circumferential surface a1 and the outer circumferential surface b1 of the holder 15 is in abutment with the stepped portion constituting the border between the inner circumferential surface a2 and the inner circumferential surface b2 of the housing 5, and therefore, there is caused no such situation that the holder 15 moves with the packing 13 pressed inwards by the inner circumferential surface a2 of the housing 5, whereby the packing 13 can be prevented from being turned or twisted in an ensured fashion.

The elongated projecting portion 41 is formed on the outer circumferential surface a1 of the holder 15 along the entire circumference thereof. Therefore, for example, even in the event that the holder 15 is inserted while being inclined relative to the axial direction of the accommodation space, the outer circumferential surface of the packing 13 can be prevented from being pressed inwards by the inner circumferential surface a2 of the housing 5 along the entire circumference thereof. Consequently, not only can the reliability of the sealing structure be enhanced, but also the workability in mounting the holder 15 in the housing 5 can be enhanced.

It is to be noted that the invention is not limited to the above described embodiments, but various modifications, improvements, and so on can be appropriately made. Besides, materials, shapes, sizes, numbers, positions to be arranged, and so on of constituent elements in the above described embodiment are not limited, provided that the invention can be achieved.

For example, in the embodiment, while the outer circumferential surface a1 of the holder 15 is described as forming the rectangular circumference section, a configuration may be adopted in which the outer circumferential surface of the holder 15 forming a circular circumferential section, that is, the holder 15 is formed into a circular cylindrical shape, and the accommodation space in the housing 5 is formed into a circular cylindrical shape which matches the circular cylindrical shape of the holder 15. In this case, too, by forming a elongated projecting portion on the outer circumferential surface of the holder so as to extend along the entire circumference thereof and by forming a recess portion into which the elongated projecting portion can be inserted on the inner circumferential surface of the housing 5 so as to extend along the entire circumference thereof, the same advantage as that obtained by the embodiment can also be obtained.

In the embodiment, while the elongated projecting portion 41 is described as projecting higher than the outer circumferential surface a1 of the packing 13 which is mounted on the outer circumferential surface a1 of the holder 15 as viewed in the section of the holder 15 in the axial direction, a configuration may be adopted in which the elongated projecting portion 41 is formed at least as high as the outer circumferential surface a1 of the packing 13 which is mounted on the outer circumferential surface a1 of the holder. In this case, when the holder 15 is inserted into the housing 5, the outer circumferential surface of the packing 13 is brought into contact with the inner circumferential surface a2 of the housing 5. However, a force which would deform the packing 13 is applied to the outer circumferential surface of the packing 13 in no case. Thus, the same advantage as that obtained by the embodiment can also be obtained.

In this embodiment, while the stepped portion which constitutes the border between the outer circumferential surface a1 and the outer circumferential surface b1 of the holder 15 is described as being brought into abutment with the stepped portion which constitutes the border between the outer circumferential surface a2 and the outer circumferential surface b2 of the housing 5 when the elongated projecting portion 41 is inserted into the recess portion 43, there will be no problem even in the event that the stepped portions of the holder 15 and the housing 5 are not brought into abutment with each other, provided that the movement of the holder 15 in the inserting direction can be locked by the insertion of the elongated projecting portion 41 into the recess portion 43.

In the embodiment, while the holder 15 is described as being inserted into the opening portion 37 in the housing 5 in whole to thereby be mounted in the opening portion 37, a configuration may be adopted in which the insertion of the holder 15 into the opening portion 37 is limited to part thereof and the part of the holder 15 inserted into the opening portion 37 is mounted in the opening portion 37. Even in the event that the configuration is adopted, the sealing structure of the embodiment can be attained by mounting a packing on an outer circumferential surface of the part which is inserted into the opening portion 37. Therefore, the same advantage as that obtained by the embodiment can also be obtained.

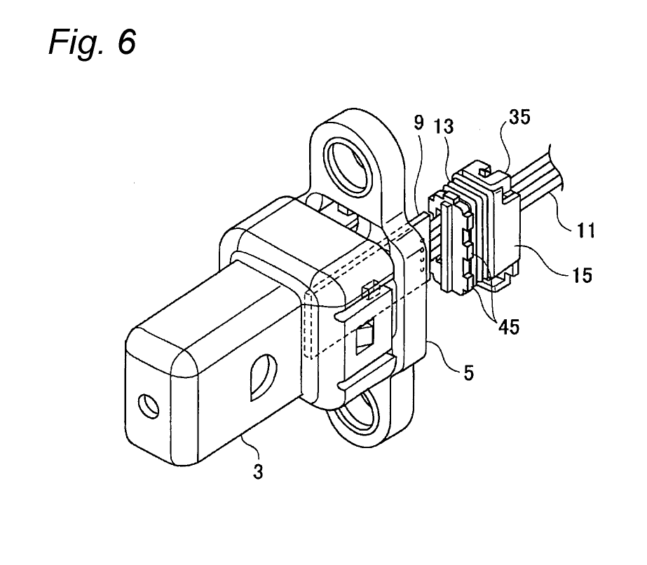

In the embodiment, while the elongated projecting portion 41 is described as being formed on the outer circumferential surface a1 of the holder 15 along the entire circumference thereof, a configuration may be adopted in which elongated projecting portions 45 are provided at plural locations in the circumferential direction on the outer circumferential surface a1 of the holder 15 as shown in FIG. 6. According to this configuration, the resistance generated when the holder 15 is inserted into the housing 5 can be reduced, thereby making it possible to enhance the workability in inserting the holder 15 into the housing 5. When the circumferential surface a1 of the holder 15 is made up of the rectangular circumferential sides, in order to prevent the packing 13 from being turned or twisted, the elongated projecting portion 45 is to be provided at least one on each side.

In view of the above, according to the configuration described above, when the holder is inserted into the opening portion in the housing, the holder is inserted while the elongated projecting portion formed on the outer circumferential surface of the holder is in abutment with the inner circumferential surface of the opening portion. Therefore, there is caused no such situation that the packing which is equal to or lower in height than the elongated projecting portion as viewed in the axial section of the holder is pressed inwards by the inner circumferential surface of the housing. Then, when the elongated projecting portion is inserted into the recess portion on the inner circumferential surface of the housing, the outer circumferential surface of the packing is pressed inwards by the inner circumferential surface of the housing, whereby the gap between the outer circumferential surface of the holder and the inner circumferential surface of the housing is sealed. Consequently, while the holder moves within the housing with the outer circumferential surface of the elongated projecting portion kept in contact with the inner circumferential surface of the housing, no external force is applied to the packing, or even when there is any external force applied to the packing, it will be a small force. Therefore, the packing can be prevented from being turned or twisted. In addition, in the event that the recess portion is formed so that the holder is not moved in the inserting direction once the elongated projecting portion fits in the recess portion, the packing can be prevented from being turned or twisted in an ensured fashion.

According to the sealing structure of the invention, the turning or twisting of the packing can be prevented which would otherwise be caused when the holder is inserted into the housing.

The present application is based on Japanese Patent Application No. 2011-037916 filed on Feb. 24, 2011, the contents of which are incorporated herein by way of reference.

What is claimed is

1. A sealing structure comprising:
a housing, having an accommodation space for accommodating an electronic part and an opening portion communicated with the accommodation space;
a holder, holding the electronic part and a wire connected to the electronic part, and configured to be inserted into the opening portion in an axial direction of the holder; and
an annular packing provided on an outer circumferential surface of the holder, and configured to be disposed between an inner circumferential surface of the opening portion and the outer circumferential surface of the holder so as to seal off the accommodation space in a state where the holder is inserted in the housing,
wherein an elongated projecting portion is formed on the outer circumferential surface of the holder in a position forward in an inserting direction of the holder than the annular packing,
wherein the elongated projecting portion projects than the annular packing in a radial direction of the holder,
wherein a recess portion is formed on the inner circumferential surface of the opening portion so that the elongated projecting portion is inserted therein, and
wherein the recess portion has such a depth that the annular packing is pressed by the inner circumferential surface of the opening portion in a state where the elongated projecting portion is inserted into the recess portion.

2. The sealing structure as set forth in claim 1, wherein
the elongated projecting portion is formed along an entire circumference of the outer circumferential surface of the holder.

3. The sealing structure as set forth in claim 1, wherein
the elongated projecting portion includes a plurality of projections formed at plural circumferential locations on the outer circumferential surface of the holder.
